(19) United States
(12) Patent Application Publication
(10) Pub. No.: US 2026/0150713 A1
(43) Pub. Date: May 28, 2026

(54) HYBRID-MATERIAL LEADS FOR SOLDERLESS COUPLING OF AN ELECTRONIC COMPONENT

(71) Applicant: SEMICONDUCTOR COMPONENTS INDUSTRIES, LLC, Scottsdale, AZ (US)

(72) Inventor: Seungwon IM, Bucheon (KR)

(73) Assignee: SEMICONDUCTOR COMPONENTS INDUSTRIES, LLC, Scottsdale, AZ (US)

(21) Appl. No.: 18/956,300

(22) Filed: Nov. 22, 2024

(51) Int. Cl. H01L 23/495; H01L 21/48; H01L 23/00; H01L 23/373; H01L 25/07; H02M 7/00; H05K 3/32

(52) U.S. Cl. CPC H10W 70/457; H02M 7/003; H05K 3/328; H10W 70/048; H10W 70/451; H10W 70/465; H10W 70/466; H10W 70/481; H10W 90/00; H10W 90/811; H05K 2203/0285; H05K 2203/0292; H10W 40/255; H10W 72/07531; H10W 72/07536; H10W 72/07631; H10W 72/07636; H10W 90/754; H10W 90/756; H10W 90/764; H10W 90/766

(57) ABSTRACT

Hybrid-material leads for solderless coupling of an electronic component are described herein. An illustrative apparatus includes a first substrate, a semiconductor die physically coupled with the first substrate, and a plurality of leads extending from a device package containing the first substrate and the semiconductor die. The plurality of leads in this example includes a hybrid-material lead that is electrically coupled with the semiconductor die and constructed of a first conductive material and a second conductive material. The first conductive material of this hybrid-material lead may be configured to maintain a rigid structure within an acoustic field while the second conductive material may be configured to plastically deform within the acoustic field to bond to a second substrate. Corresponding devices and fabrication methods are also disclosed.

### TECHNICAL FIELD

This description relates to electronic device assemblies. More specifically, this description relates to semiconductor device packages.

### BACKGROUND

Packaging plays a critical role in ensuring the proper function, reliability, and ease of use of electronic components. Proper packaging of electronic components may serve various roles. For example, one function of a package may be to protect a delicate silicon die inside the package from physical damage, contamination, electrostatic discharge (ESD), etc., since these threats could render the component inoperable if the die is not properly protected. Similarly, the package may also provide a barrier against moisture and exposure to other environmental elements that could lead to degradation and malfunction of the component. Another role of the package may be to facilitate electrical connections between the internal circuitry of the component and external circuitry (e.g., of a circuit board to which the electronic component is coupled, etc.). For example, metal pins, leads, bumps, and other such features may allow for the electrical component to be soldered onto or otherwise connected to a printed circuit board. Heat dissipation may also be provided by packaging that is configured to facilitate heat transfer away from operational elements of the component (e.g., the semiconductor die inside the device package). Packaging may also include markings or labels that indicate important information about the component (e.g., a part number, manufacturer, electrical specifications, etc.) to facilitate proper identification, handling, and placement on the circuit board.

### SUMMARY

Various electronic components (e.g., integrated circuits, etc.) are packaged such that a molding material encloses internal electronics, while leads or other suitable electrical connections (e.g., pins, bumps, etc.) protrude from the molding material to facilitate the electronic component being connected to external circuitry. Typically, leads of an electronic component packaged in this way would be integrated as part of a larger circuit or device by being soldered to a substrate such as a printed circuit board. As described in more detail herein, however, the heat introduced to an electronic component by a soldering process may, under certain circumstances, cause damage to the component. While these effects may be avoided by careful adherence to certain procedural actions during the manufacturing of the device using the electronic component, these actions ultimately complicate the manufacturing process and make it more costly (e.g., in terms of time, complexity, required expertise, labor, special equipment, convenience, etc.). Accordingly, as detailed below, apparatuses (e.g., electronic components) disclosed herein use device packages featuring hybrid-material leads to allow for solderless coupling of the apparatuses. In this way, these costs may be avoided or mitigated and other advantages described herein may be provided.

As one example implementation, an apparatus (e.g., an electronic component such as a packaged semiconductor device) may include: 1) a first substrate; 2) a semiconductor die physically coupled with the first substrate; and 3) a plurality of leads extending from a device package containing the first substrate and the semiconductor die. In this example, the plurality of leads may include a hybrid-material lead that is electrically coupled with the semiconductor die. As described in more detail below, a hybrid-material lead refers to a lead constructed of a first conductive material and a second conductive material. For instance, in this example, the first conductive material may be configured to maintain a rigid structure within an acoustic field, while the second conductive material may be configured to plastically deform within the acoustic field to bond to a second substrate. In this way, the hybrid-material lead may be solderlessly coupled to the second substrate without introducing the heat required by the soldering process.

As another example implementation, a method (e.g., a manufacturing process for fabricating an apparatus such as the apparatus described above) may include: 1) preparing an internal substrate; 2) coupling a semiconductor die with the internal substrate; 3) mounting the internal substrate on a metal portion of a device package, the metal portion including a plurality of leads each constructed of a first conductive material and a second conductive material, the first conductive material being configured to maintain a rigid structure within an ultrasonic field produced by an ultrasonic welding tool and the second conductive material being configured to plastically deform within the ultrasonic field to bond to an external substrate; 4) establishing electrical connections from the plurality of leads to the internal substrate and the semiconductor die; and 5) encasing the internal substrate, the semiconductor die, the electrical connections, and a portion of each of the plurality of leads in a molding material of the device package.

As yet another example implementation, a power inverter module (e.g., an automotive high-power module (AHPM), etc.) may include: 1) a substrate; 2) a heatsink; and 3) a plurality of chips each physically coupled with the heatsink and electrically coupled with the substrate. In this example, the plurality of chips includes a chip having a plurality of semiconductor dies contained within a device package from which a plurality of leads extends. The plurality of leads includes a lead constructed of a first conductive material and a second conductive material, the first conductive material being configured to maintain a rigid structure within an acoustic field, and the second conductive material being configured to plastically deform within the acoustic field to bond to the substrate while the acoustic field is produced and the lead is in physical contact with the substrate.

Each of the preceding example implementations will be understood to be illustrative of the types of implementations that are consistent with the following description. It will be understood that these examples are not intended to be limiting and that any of the aspects mentioned above or described herein may be used with any of the implementations in accordance with principles described herein. The details of these and other implementations are set forth in the accompanying drawings and the description below. Other features will also be apparent from the following description, drawings, and claims.

### BRIEF DESCRIPTION OF THE DRAWINGS

FIG. 1 shows an illustrative electronic component featuring hybrid-material leads for solderless coupling in accordance with principles described herein.

FIG. 2 shows an illustrative implementation of the electronic component of FIG. 1 from a variety of viewpoints in accordance with principles described herein.

FIG. 3 shows an illustrative contrast between a half-bridge circuit implemented by discrete electronic components and a half-bridge circuit implemented using multiple dies in a single device package in accordance with principles described herein.

FIG. 4 shows illustrative aspects of a power inverter module including a plurality of half-bridge circuits in accordance with principles described herein.

FIG. 5 shows an illustrative method for fabricating an electronic component featuring hybrid-material leads for solderless coupling in accordance with principles described herein.

FIG. 6A shows an illustrative internal substrate configured for use in electronic components in accordance with principles described herein.

FIG. 6B shows a plurality of semiconductor dies being physically coupled with the internal substrate in accordance with principles described herein.

FIG. 6C shows an example process for fabricating a metal portion of a device package with a plurality of hybrid-material leads in accordance with principles described herein.

FIG. 6D shows illustrative aspects of the fabrication process for the hybrid-material leads of the metal portion of the device package in accordance with principles described herein.

FIG. 6E shows the internal substrate being mounted on the metal portion of the device package in accordance with principles described herein.

FIG. 6F shows electrical connections established between the plurality of hybrid-material leads of the device package and the plurality of dies on the internal substrate in accordance with principles described herein.

FIG. 6G shows illustrative molding material in which other components of the device package are encased in accordance with principles described herein.

FIG. 6H shows an example process for finishing the apparatus in accordance with principles described herein.

FIG. 6I shows example aspects of solderless coupling of the apparatus with an external substrate in accordance with principles described herein.

### DETAILED DESCRIPTION

Device packaging for electronic components protects delicate electronics (e.g., discrete electronic components, integrated circuits, etc.) while also making these components easier to use and providing other benefits (e.g., heat dissipation, product marking, etc.). Packaged electronic components generally provide leads or other electrical connections that protrude from a protective molding that encases the more delicate elements of the part (e.g., semiconductor dies, inner connections and substrates, etc.). These leads facilitate the electronic component being connected to external circuitry such as by being electrically connected, along with other components, to a printed circuit board (PCB).

Typically, electrical connections between the leads of an electronic component and pads on a substrate such as a PCB rely on bonding techniques that require significant heat. For example, when a lead is properly aligned with a PCB pad or other connection point of the substrate, a solder material may be introduced to the area along with heat sufficient to reflow (i.e., melt) the solder material to thereby form a solder joint when the reflowed material cools and solidifies. As another example, a lead may become electrically fused to a pad by a sintering process involving heat and pressure that cause a powdered sintering material to fuse the lead and the pad together. While either of these techniques may allow for the creation of strong connections between the electronic component and the substrate, however, the heat associated with the soldering and/or sintering processes may create technical problems for certain components and/or under certain circumstances.

As one example, certain electronic components, when exposed to ambient conditions, tend to take on and trap ambient moisture from the air. Natural moisture (e.g., water vapor, etc.) in the room where the component is to be placed and connected to a substrate (e.g., a PCB) may diffuse into the molding of the device package and become trapped in spaces between the plastic body of the molding and the circuitry that is encased within this body (e.g., an inner substrate, one or more semiconductor dies, inner wirebonds or other electrical connections, etc.). If the moisture issue is not addressed, the expansion of trapped vapor, when the electronic component is exposed to the heat of a soldering or sintering process, may cause cracking, delamination, deformation, disconnection of inner wires, and/or other such issues for the electronic component and the circuitry within which it is being used.

One way to avoid these outcomes is by careful adherence to predetermined rules and standards (e.g., based on predetermined parameters that have been characterized for the parts and the environment). For example, after fabrication, electronic components may be baked to remove moisture and may be dry packed (i.e., sealed in low-moisture or moisture-free antistatic bags) before being distributed for use (e.g., sold, shipped, or otherwise distributed for use in other circuits). This process of baking and dry packing may add significant cost (e.g., in terms of material costs, time, complexity, etc.) to the fabrication and distribution process for the electronic components.

Moreover, even when such measures are taken to keep the electronic components free of moisture, moisture performance parameters for the electronic components need to be carefully observed throughout the product's lifetime to ensure that damage is not incurred later on (e.g., when the electronic component inevitably emerges from the antistatic bag). For example, a given electronic component may be rated at a particular moisture sensitivity level (MSL) that dictates how much time the component may be outside of a moisture-free bag and exposed to ambient conditions before a problem is likely to occur. Hence, even in the best-case scenario where no moisture problem ever actually arises, the obligation to monitor and observe these types of parameters may create undesirable manufacturing limitations that lead to difficulty, inconvenience, decreased yields, and/or other risks and undesirable outcomes. Indeed, procedural manufacturing requirements around component moisture sensitivity may ultimately complicate the manufacturing process and make it more costly in terms of time, complexity, required expertise, labor, special equipment, convenience, and/or other aspects.

As detailed further below, hybrid-material leads described herein for solderless coupling of electronic components provide at least one technical solution to the technical problems described above. As used herein, a hybrid-material lead refers to a lead of a device package that is constructed from at least two different materials to facilitate coupling (e.g., bonding, fusing, connecting, welding, etc.) of the lead to a substrate by techniques requiring considerably less heat (or at least more localized heat) soldering and sintering techniques such as described above. For example, a first material used for a hybrid-material lead may be a conductive material that is configured to maintain a rigid structure within a particular acoustic field such as an ultrasonic field produced by an ultrasonic welding tool. A second material used for the hybrid-material lead may then be a conductive material that is configured to plastically deform within such an acoustic field so as to bond to the substrate (e.g., the PCB pad or the like). Methods for making and using hybrid-material leads to allow for solderless coupling of electronic components (e.g., direct joining of the electronic components to substrates by ultrasonic welding or other acoustics-based, solderless techniques) are described in detail below as technical solutions to the various technical problems outlined above.

A variety of technical effects may arise as a consequence of using hybrid-material leads described herein for solderless coupling of electronic components. As one example, hybrid-material leads described herein obviate the need for newly packaged apparatuses (i.e., electronic components fabricated with device packages) to undergo baking and dry packing processes such as described above. Even if small amounts of moisture are able to diffuse into the molding of a given electronic component, this moisture may pose no threat to the device if the device is never to be exposed to the significant heat of a soldering or sintering procedure. As another example of a beneficial technical effect of hybrid-material leads described herein, these leads may be coupled to a substrate without further material such as solder or sintering material being introduced to create the bonding joint. For instance, when an ultrasonic welding tool introduces an acoustic field (e.g., an ultrasonic field produced by the tool) to the area where a hybrid-material lead is in contact with the substrate, the second conductive material may plastically deform in a manner that allows it to directly bond (e.g., fuse, weld, etc.) to the substrate even while the first conductive material maintains a rigid structure (i.e., does not plastically deform) so that the hybrid-material lead retains its desired shape. All of this is performed with no additional joint forming material (e.g., solder, sintering material, etc.), with minimal added heat that can be very localized to the lead so as to not heat the body of the component, and with other such benefits. As such, any moisture that happens to have diffused into the device package will not be at risk of vaporizing and expanding to cause the problems described above.

Other beneficial technical effects of hybrid-material leads described herein may also arise as these device packages are constructed, distributed, and used in various types of circuits. For instance, as detailed below, these hybrid-material leads may enable the use of multi-die apparatuses in which several semiconductor dies (e.g., silicon (Si) dies, silicon carbide (SiC) dies, etc.) are integrated into a single package. This may help support more compact circuitry when such apparatuses are used, which may in turn reduce costs and provide other benefits. Four field effect transistor dies may be integrated into a single device package, for example, such that the apparatus implements a half-bridge circuit that, when combined with other similar integrated circuit components (e.g., a total of three half-bridge integrated circuits on a shared substrate in one example), a compact, lightweight, and low-cost device such as a power inverter module (e.g., an automotive power inverter) may be created. Such modules may provide cost reduction, power savings, increased efficiency, increased effectiveness, and other advantages as compared to more conventional modules.

Various implementations will now be described in more detail with reference to the figures. It will be understood that the particular implementations described below are provided as non-limiting examples and may be applied in various situations. Additionally, it will be understood that other implementations not explicitly described herein may also fall within the scope of the claims set forth below. Hybrid-material leads for solderless coupling of electronic components in accordance with principles described herein may result in any or all of the technical benefits mentioned above, as well as various additional technical benefits that will be described and/or made apparent below.

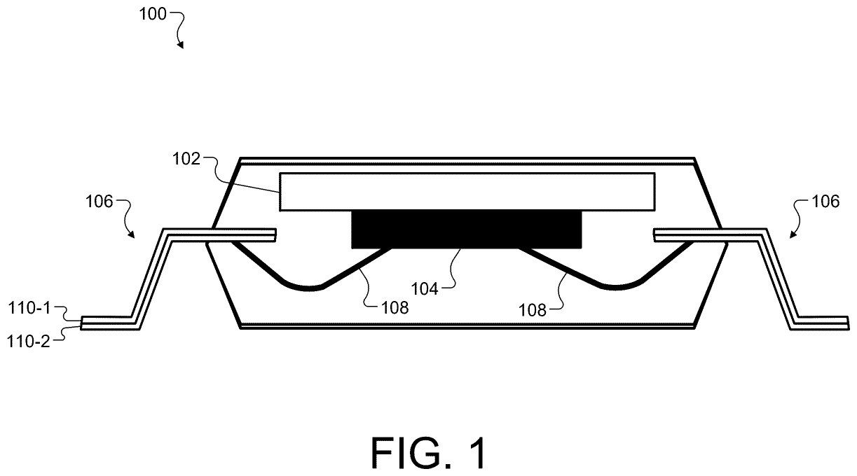

FIG. 1 shows an illustrative electronic component featuring hybrid-material leads for solderless coupling in accordance with principles described herein. More particularly, as shown, an apparatus 100 (also referred to as an electronic component) is shown to include a first substrate 102, a semiconductor die 104 physically coupled with the first substrate 102, and a plurality of leads 106 extending from a device package containing the first substrate 102 and the semiconductor die 104. As further shown in FIG. 1, the plurality of leads 106 of apparatus 100 may include at least one lead 106 that is electrically coupled (e.g., directly or indirectly through other circuitry) with the semiconductor die 104. For example, this coupling may be via a wire 108 as shown, or via another suitable conductor (e.g., a clip, etc.). As illustrated in FIG. 1, this lead 106 may be a hybrid-material lead constructed of a first conductive material 110-1 and a second conductive material 110-2. The first conductive material 110-1 may be configured to maintain a rigid structure within an acoustic field (e.g., an ultrasonic field produced by an ultrasonic welding tool such as described in more detail below). Meanwhile, the second conductive material 110-2 may be configured to plastically deform within the acoustic field to bond to a second substrate (not explicitly shown in FIG. 1). Each of these elements will now be described in more detail.

As shown, the first substrate 102 may be an internal substrate contained within the device package, while the second substrate (not explicitly shown in FIG. 1) may be an external substrate to which the device package is coupled. In other words, the first substrate 102 may be internal to the device package (i.e., and included as part of apparatus 100), while the second substrate may be external to the device package (and separate from apparatus 100 in this example). The internal substrate 102 may be implemented as a direct-bonded metal (DBM) substrate implemented by a patterned layer of metal bonded to a ceramic substrate. For example, as described in more detail below, the internal substrate 102 may be a direct-bonded copper (DBC) substrate or another similar substrate using a suitable metal or conductor other than copper. The external substrate may then be implemented by a printed circuit board (PCB) of a larger circuit such as a power inverter module (described in more detail below) or another suitable electronic circuit module.

The semiconductor die 104 shown in apparatus 100 may be implemented by a silicon (Si) die, a silicon carbide (SiC) die, or a die of another suitable semiconductor material. In some examples, semiconductor die 104 could implement a field effect transistor (FET) such as a metal-oxide-semiconductor field effect transistor (MOSFET). In the example where apparatus 100 is to be used as part of a power inverter module, for instance, the semiconductor die 104 could implement a single power transistor configured to direct significant amounts of current for use in automotive or other high-power industrial applications. In other examples, semiconductor die 104 could include an integrated circuit that includes many transistors (e.g., implementing digital logic, etc.) or other circuitry (e.g., mixed analog/digital circuitry, etc.).

While a single semiconductor die 104 is shown in the example of apparatus 100, it will be understood (as well as described and illustrated in more detail below) that apparatus 100 could include, in certain implementations, a plurality of semiconductor dies. For instance, each of these semiconductor dies could be physically coupled with the internal substrate 102 and integrated within the device package and the illustrated semiconductor die 104 would be understood to be included as one of the plurality of semiconductor dies in this example. In the example where a power inverter module is to be created, such a plurality of semiconductor dies could include four semiconductor dies each implementing a separate FET, the four semiconductor dies being electrically interconnected such that apparatus 100 implements a half-bridge circuit configured for use in the power inverter module. While each of the semiconductor dies in such examples could use the same materials and/or technologies, it may also be possible for hybrid dies to be used. For example, one or more semiconductor dies could be silicon (Si) dies while one or more other semiconductor dies could be silicon carbide (SiC) dies, all integrated within a same device package.

The side cutaway view of apparatus 100 provided by FIG. 1 shows two leads 106 of a plurality of leads 106 that will be understood to be included as part of the electronic component. However, as a single lead 106 is sufficient to refer to as an example of a hybrid-material lead implementing the principles described herein, the focus of the following description will be on a single hybrid-material lead (e.g., the lead 106 on the left-hand side of FIG. 1, for example). It will be understood that, in at least some implementations, each lead 106 of the plurality of leads 106 may be configured to bond to the external substrate in the same or similar ways described for the particular lead 106 explicitly described.

As labeled on the particular lead 106 in FIG. 1, first conductive material 110-1 may be disposed on a first side of the lead 106 configured to physically contact an acoustic welding tool (e.g., an ultrasonic welding tool, not explicitly shown in FIG. 1) while an acoustic field (e.g., an ultrasonic field) is produced by the tool. In other words, as shown, first conductive material 110-1 may extend along an upper side of the lead 106 in this orientation (facing up away from the external substrate where apparatus 100 will be coupled). Second conductive material 110-2 may then be disposed on a second side of the lead opposite the first side and configured to physically contact the external substrate while the acoustic field (e.g., the ultrasonic field) is produced. In other words, as shown, second conductive material 110-2 may extend along a lower side of the lead 106 in this orientation (facing down toward the external substrate where apparatus 100 will be coupled).

As will be described and illustrated in more detail below, there may be a variety of ways that the first and second conductive materials can be overlaid together to form lead 106, as well as a variety of materials that may be used to achieve the desired effect of the first conductive material maintaining a rigid structure within an acoustic field while the second conductive material plastically deforms to bond to the external substrate. As one example, first conductive material 110-1 may be copper and second conductive material 110-2 may be aluminum. Example processes for fabricating a leadframe (i.e., a metal or conductive portion of the device package that includes the plurality of leads 106) including hybrid-material leads such as lead 106 will be described and illustrated below.

Electrical connections between the semiconductor die 104, other semiconductor dies (not explicitly shown in FIG. 1), and other circuitry within the device package (e.g., pads on first substrate 102, other embedded electronic components not explicitly shown, etc.) may be implemented in any suitable way. For instance, a wire bonding technique resulting in wires 108 shown in FIG. 1 represent one way that electrical connections can be established for apparatus 100. Electrical connections can be established, for example, using a soldering technique to bond conductive wires 108 or other suitable conductive devices (e.g., conductive clips, etc.) to the plurality of leads 106, the internal substrate 102, the semiconductor die 104, and so forth. As another example, electrical connections could be established using a sintering technique to bond the conductive wires 108 or other conductive devices (e.g., clips, etc.) to the plurality of leads 106, the internal substrate 102, and/or any semiconductor dies that may be included within the device package (semiconductor die 104, etc.).

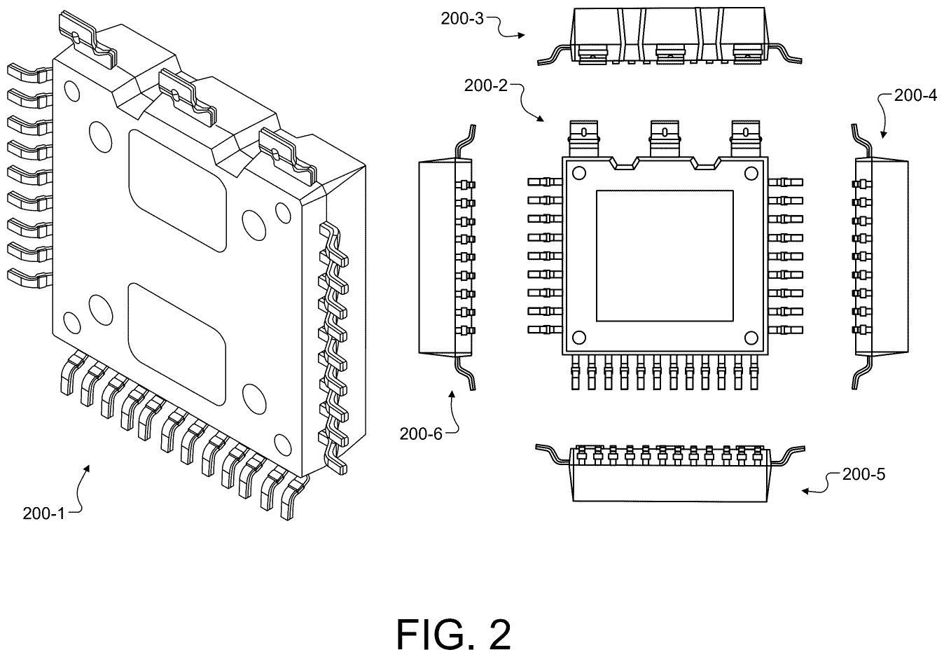

FIG. 2 shows an illustrative implementation of apparatus 100 (i.e., an electronic component in accordance with principles described above in relation to FIG. 1) from a variety of viewpoints 200-1 to 200-5. For example, as mentioned above, this electronic component may include several semiconductor dies internally connected in a manner that forms a half-bridge circuit or other suitable circuitry.

A half-bridge circuit is a basic power electronic circuit that implements power switches (e.g., formed from MOSFETs, Insulated Gate Bipolar Transistor (IGBTs), or other suitable transistors) to control the flow of current to a load. Half-bridge circuits such as represented by this implementation of apparatus 100 may serve as building blocks for power electronic converters, including power inverter modules described herein. For example, a plurality of half-bridge circuits (e.g., several apparatuses 100) may be electrically combined to form a full-bridge inverter allowing for bidirectional control of voltage and current. In the context of an automotive application, a power inverter module (including a full-bridge inverter) may facilitate driving electric motors in various directions and speeds as the power switches are turned on and off rapidly to control the flow of current.

Viewpoint 200-1 shows the example implementation of apparatus 100 from a perspective view that mostly shows the bottom of the electronic component (i.e., the side that will be connected to an external substrate such as a PCB). Viewpoint 200-2 shows the component straight-on from a top view, while viewpoints 200-3, 200-4, 200-5, and 200-6 each show the component straight-on from each of the four sides of the apparatus. In each of these figures, a plurality of leads (e.g., implementing leads 106 described above) are shown to be extending out from the molding of the apparatus's package. Each of these leads is shown to be a hybrid-material lead that includes both a first conductive material on one side (e.g., the top) and a second conductive material on the opposite side (e.g., the bottom). These materials will be understood to exhibit the properties described herein for other hybrid-material leads and to therefore help provide the same benefits and technical effects that have been described.

As mentioned above, electronic components described herein (e.g., implementations of apparatus 100) may integrate, into a singular device package, a plurality of semiconductor dies coupled to the same internal substrate and internally connected to provide desired circuit functions (e.g., a half-bridge circuit or other suitable circuitry). More particularly, an implementation of apparatus 100 may include a plurality of semiconductor dies each physically coupled with the internal substrate and integrated within the device package, where this plurality of semiconductor dies includes four semiconductor dies each implementing a field effect transistor (e.g., a MOSFET) and where the four semiconductor dies are electrically interconnected such that the apparatus implements a half-bridge circuit configured for use in a power inverter module. Along with advantages described above that arise from hybrid-material leads (which connect solderlessly to external substrates with minimal and/or highly localized heat), multi-die device packaging may provide additional technical effects (benefits and advantages) as compared to more conventional device packages that include only a single semiconductor die.

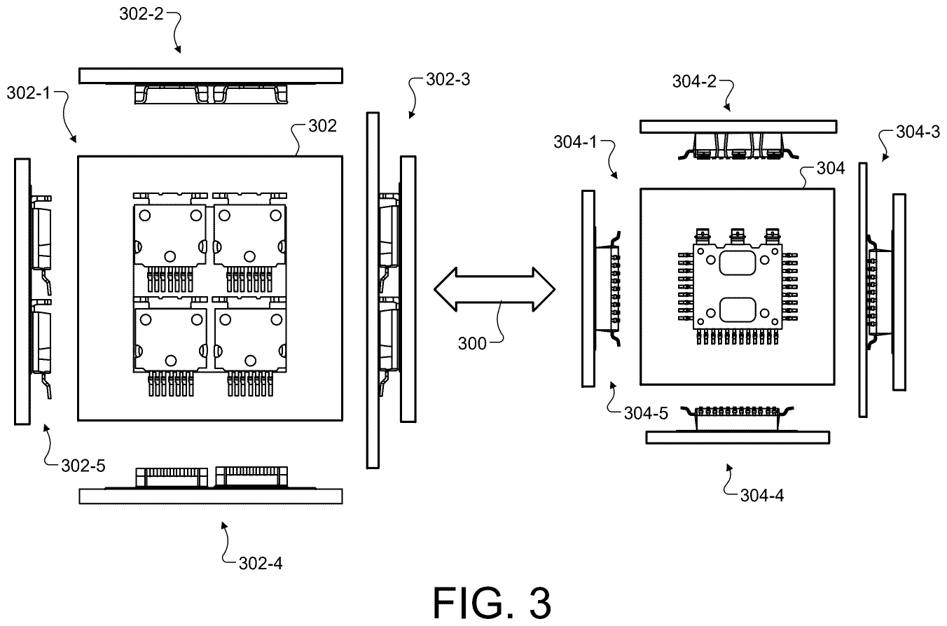

To illustrate some of these technical effects, FIG. 3 shows an illustrative contrast 300 between a half-bridge circuit 302 implemented by discrete electronic components and a half-bridge circuit 304 implemented using multiple dies in a single device package in accordance with principles described herein. Similarly as illustrated above in FIG. 2, each of the example half-bridge circuits 302 and 304 illustrated in FIG. 3 is shown from several viewpoints. Specifically, half-bridge circuit 302 is shown from a straight-on, bottom viewpoint 302-1 and from four straight-on side viewpoints 302-2, 302-3, 302-4, and 302-5 to show the discrete electronic components from various angles. Similarly, half-bridge circuit 304 is shown from a straight-on bottom viewpoint 304-1 and from four straight-on side viewpoints 304-2, 304-3, 304-4, and 304-5 to show the single-package, multi-die electronic component from corresponding angles.

In both cases, the half-bridge circuits 302 and 304 are shown to include a housing (e.g., aluminum housing) on the top side, which may be configured to hold, connect, protect, and/or draw heat away from the components when the bottom side is connected to a substrate (e.g., a PCB) and in operation. While the housing is shown in each of the views 302-1 to 302-5 and the views 304-1 to 304-5, only views 302-3 and 304-3 show the substrate to which the bottom side may be connected.

Along with the reduced complexity of having only a single component implementing half-bridge circuit 304 as compared to the four discrete components implementing half-bridge circuit 302, contrast 300 will be understood to represent additional potential benefits such as reduced power usage and increased efficiency, reduced costs, simplified manufacturing requirements, and so forth. Additionally, as shown, the single electronic component implemented by half-bridge circuit 302 may allow for a reduced footprint that can lead to a more compact power inverter module when the half-bridge circuit 302 is used. Even in examples where apparatus 100 implements a circuit other than a half-bridge circuit, the same compactification may result by packaging multiple semiconductor dies (e.g., four SiC dies, a hybrid combination of Si and SiC dies, etc.) in a unified package instead of relying on discrete components.

In some implementations, a module (e.g., an apparatus including a semiconductor device within a package) can be included in another module. The module can be referred to as a package. For example, one or more modules can be one or more sub-modules included within another module. In other words, a first module can be included as a sub-module within a second module. Referring more particularly to modules such as are implemented by apparatus 100, these may serve as sub-modules to a larger module such as a circuit, system, or device that employs apparatus 100 and may include a plurality of instances of apparatus 100.

As one particular example, as has been mentioned, apparatus 100 could implement a half-bridge circuit (e.g., with four field effect transistors) and several apparatuses 100 could be combined within a single device to form a full-bridge circuit for a power inverter module. More specifically, a power inverter module in accordance with these principles could include: 1) a substrate (e.g., a PCB, etc.); 2) a heatsink (e.g., implemented as a housing such as the aluminum housing described in relation to FIG. 3); and 3) a plurality of chips (i.e., electronic components implementing apparatus 100) each physically coupled with the heatsink and electrically coupled with the substrate. In a particular implementation, for instance, the plurality of chips may include three chips each including four respective semiconductor dies implementing field effect transistors that are electrically interconnected to implement respective half-bridge circuits.

Regardless of how many chips or dies are included, each of the plurality of chips in these examples may have a plurality of semiconductor dies contained within a device package from which a plurality of leads extends. As has been described, each of these leads in the plurality of leads may be constructed of both a first conductive material and a second conductive material, wherein the first conductive material is configured to maintain a rigid structure within an acoustic field and the second conductive material is configured to plastically deform within the acoustic field (to couple to the substrate while the acoustic field is produced and the lead is in physical contact with the substrate). For example, as described in examples above, the acoustic field may be an ultrasonic field produced by an ultrasonic welding tool, such that each of the plurality of chips can be bonded to the substrate by an ultrasonic welding technique involving less and/or more localized heat than a soldering or sintering technique (and thereby avoiding vaporized moisture expanding to cause cracking, delamination, and/or other issues described above).

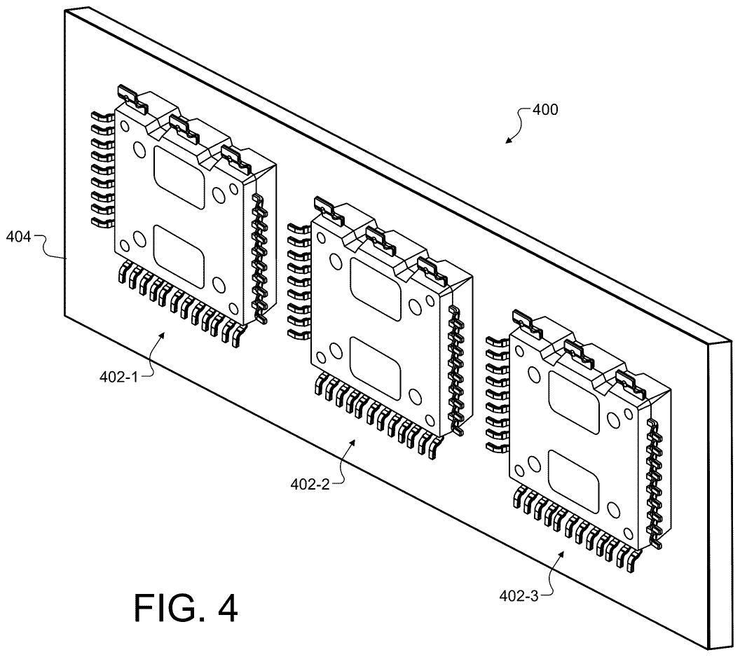

To illustrate these principles, FIG. 4 shows certain aspects of a power inverter module 400 including a plurality of half-bridge circuits 402-1, 402-2, and 402-3 in accordance with principles described herein. Just as half-bridge circuit 302 and half-bridge circuit 304 were shown above to be integrated with a housing (e.g., an aluminum housing that may act as a heatsink, as described above), the chips implementing the half-bridge circuits 402-1 to 402-3 on power inverter module 400 are shown to be integrated with a housing 404 that may serve the same purpose. For example, housing 404 may be implemented by an aluminum sheet or another suitable material that may serve to structurally hold the chips together as they are placed and attached to a substrate such as a PCB (not shown in FIG. 4), as well as to draw and dissipate heat away from the chips and perform other roles (protecting the chips, etc.).

Power inverter module 400 may be configured as a traction inverter or other power inverter suitable for automotive use or for another desired application. As such, power inverter module 400 may convert direct current (DC) power from a battery into alternating current (AC) power to drive the electric motors of an electric vehicle (EV) or hybrid electric vehicles (HEV). In this way, power inverter module 400 may facilitate control of power flow to the electric motors, affecting a vehicle's acceleration, deceleration, and overall performance. The transistors implemented by the semiconductor dies in the chips (i.e., the half-bridge circuits 402-1 to 402-3) may be implemented by MOSFETs (advantageous due to their fast switching speed, high efficiency, and relatively low cost), IGBTs (offering higher blocking voltage and current capabilities than MOSFETs to help with high-power applications), SiC MOSFETs (featuring even higher efficiency, lower losses, and higher operating temperatures compared to traditional Si MOSFETs), other suitable transistor technologies, or a hybrid combination of two or more of these.

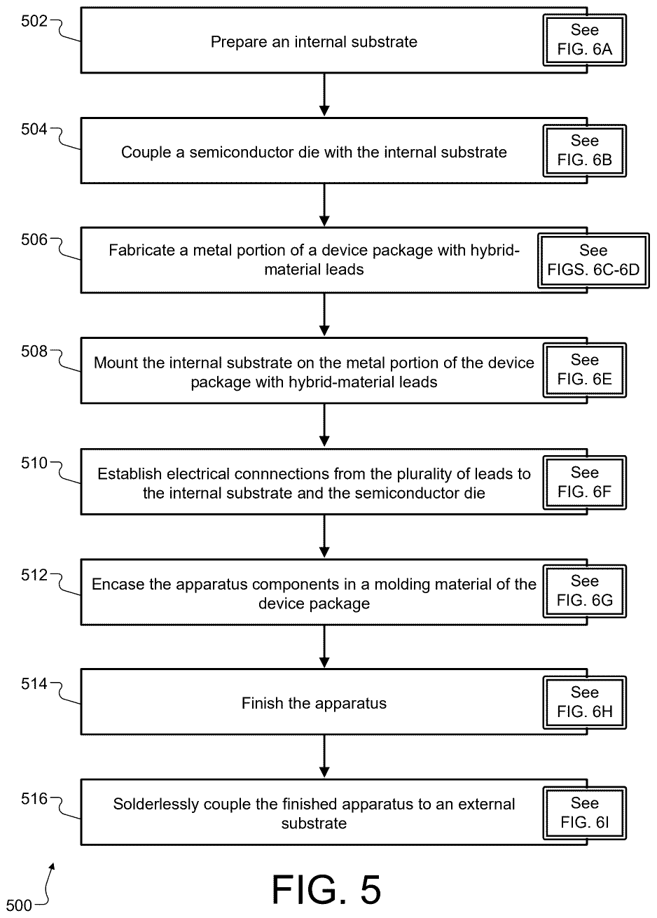

FIG. 5 shows an illustrative method 500 for fabricating an electronic component featuring hybrid-material leads for solderless coupling in accordance with principles described herein. For example, an implementation of apparatus 100, a module of which apparatus 100 serves as a sub-module (e.g., an implementation of power inverter module 400), and/or any other example apparatus implementations described herein may be assembled or constructed using steps such as shown in method 500.

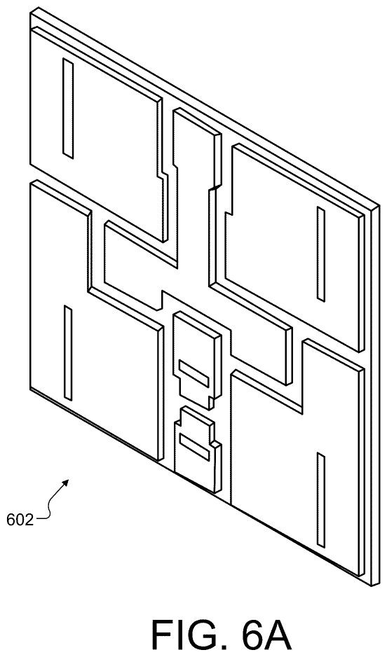

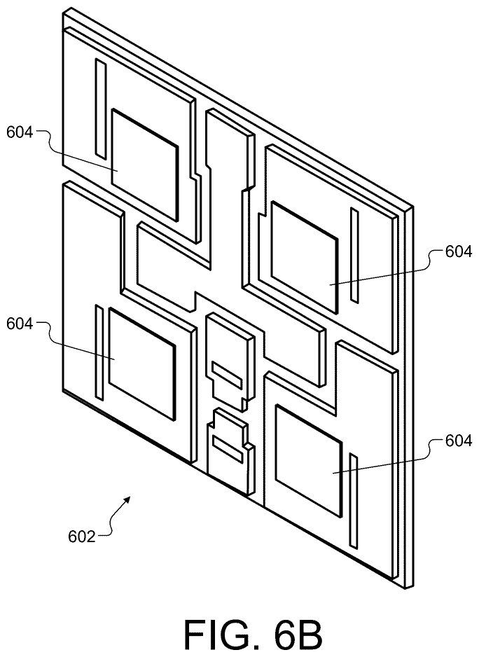

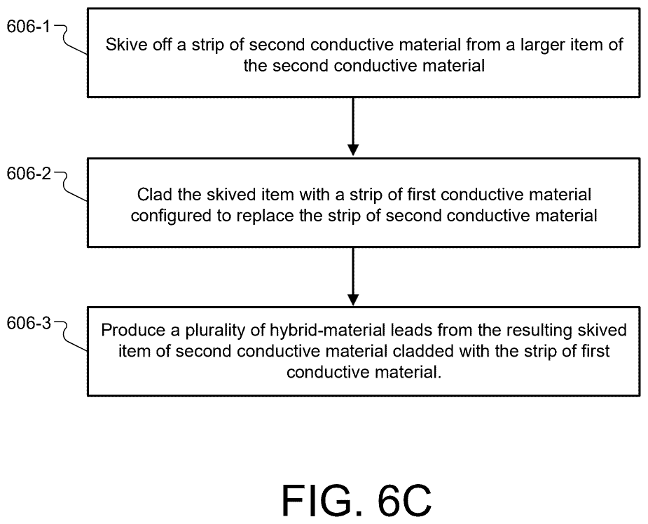

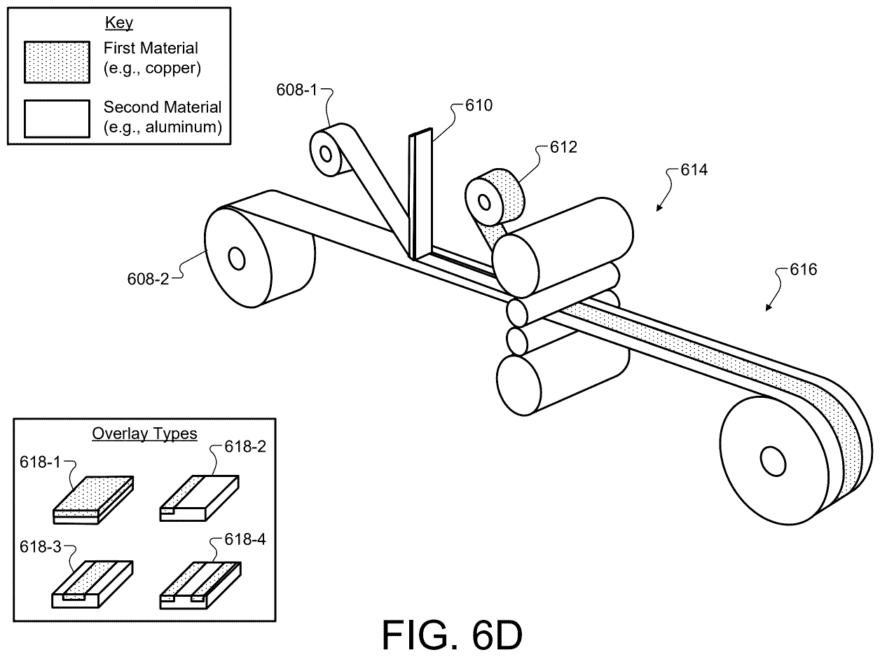

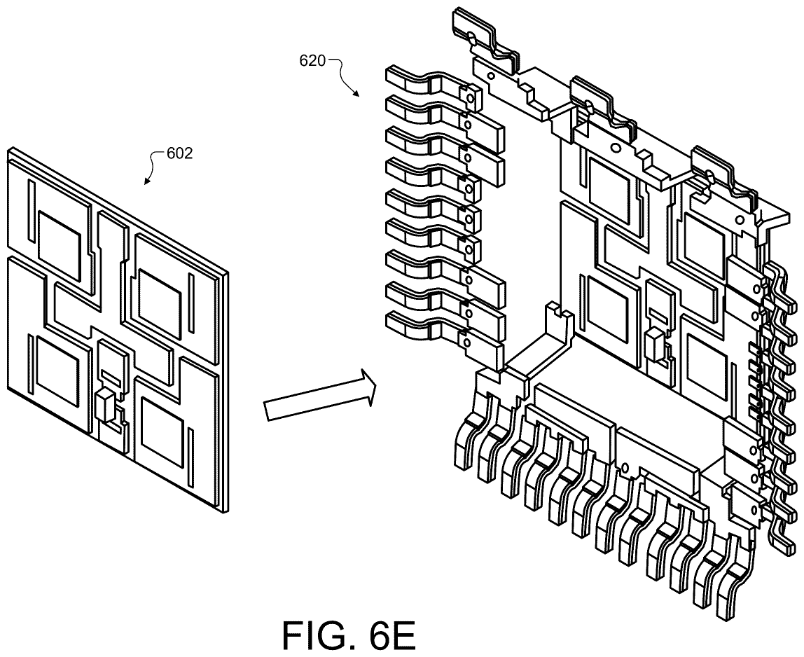

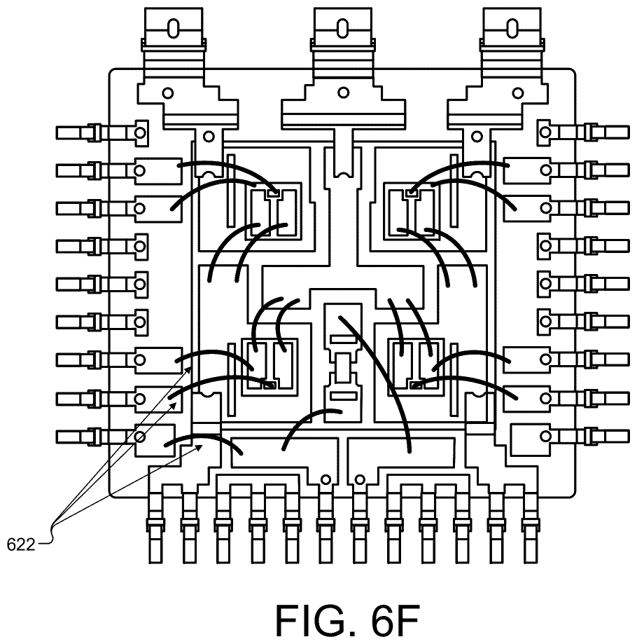

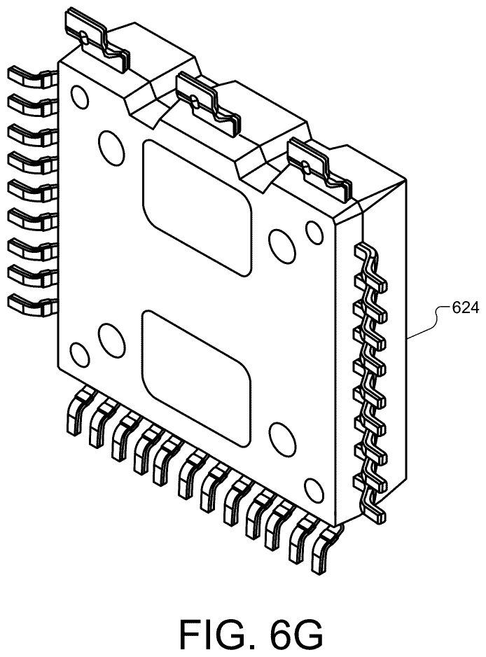

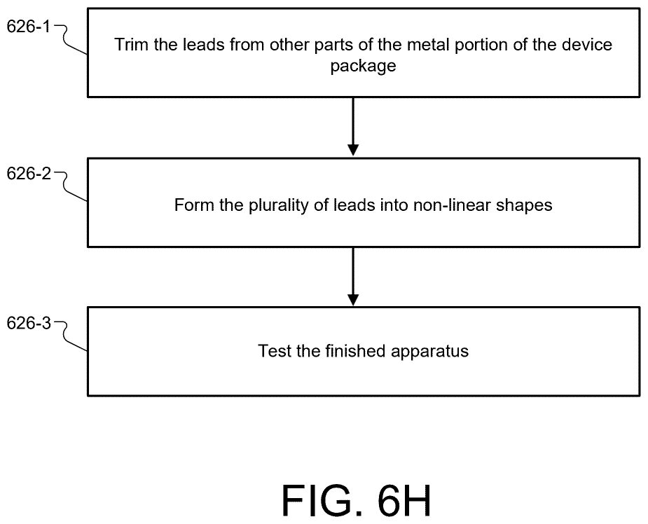

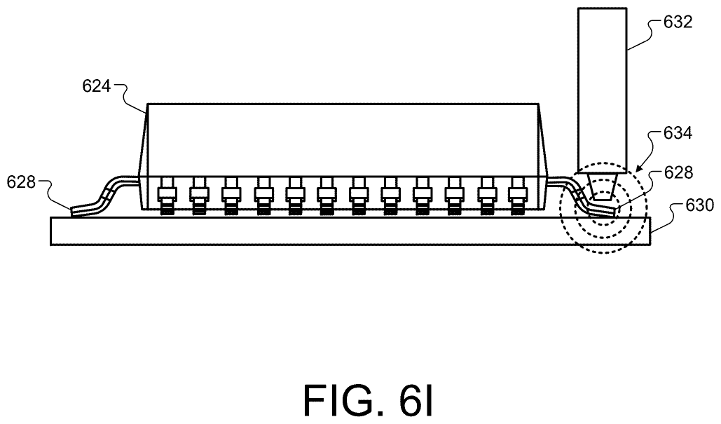

While FIG. 5 shows illustrative operations 502-516 according to one implementation, other implementations of method 500 may omit, add to, reorder, and/or modify any of the operations 502-516 shown in FIG. 5. In some examples, multiple operations shown in FIG. 5 or described in relation to FIG. 5 may be performed concurrently (e.g., in parallel) with one another, rather than being performed sequentially as illustrated and/or described. Each of operations 502-516 will now be described in more detail with reference to additional figures as noted in FIG. 5. Specifically, as shown, operation 502 will be described with reference to FIG. 6A, operation 504 will be described with reference to FIG. 6B, operation 506 will be described with reference to FIGS. 6C and 6D, operation 508 will be described with reference to FIG. 6E, operation 510 will be described with reference to FIG. 6F, operation 512 will be described with reference to FIG. 6G, operation 514 will be described with reference to FIG. 6H, and operation 516 will be described with reference to FIG. 6I.

Operation 502 is shown to involve preparing an internal substrate for use within the apparatus. For example, the internal substrate could be prepared by obtaining or procuring a substrate configured to serve the purpose of the internal substrate in the apparatus (e.g., ordering a prefabricated substrate from a supplying entity separate from an entity responsible for fabricating the implementation of apparatus 100). In other implementations, the internal substrate could be prepared by the entity responsible for fabricating apparatus 100 first performing various operations (outside the scope of this disclosure) to fabricate the internal substrate.

In some examples, the internal substrate prepared at operation 502 may be a direct-bonded metal (DBM) substrate implemented by a patterned layer of metal bonded to a ceramic substrate. To illustrate, for example, FIG. 6A shows an illustrative internal substrate 602 (e.g., a DBM substrate) configured for use in an electronic component in accordance with principles described herein.

In some implementations, a DBM substrate such as internal substrate 602 may include an insulating layer disposed between a first metal layer and a second metal layer. The insulating layer can be, for example, a ceramic layer. In some implementations, the insulating layer can be or can include, for example, a ceramic material such as alumina (Al2O3) or aluminum nitride (AlN)).

In some implementations, the first metal layer and/or the second metal layer can be or can function as a heatsink. In some implementations, the first metal layer and/or the second metal layer can be coupled to a heatsink. In some implementations, at least a portion of one or more of the first metal layer or the second metal layer can be exposed through a molding material.

In some implementations, the first metal layer and/or the second metal layer can be or can include a patterned metal layer including one or more electrically conductive traces. In some implementations, the first metal layer and/or the second metal layer can be or can include a patterned layer configured to form one or more electrical circuits, one or more conductive blind and/or through vias, and/or so forth.

In some implementations, the DBM substrate can be, or can include, a direct bonded copper (DBC) substrate. In some implementations, such as in DBC substrate implementations, the first metal layer and/or the second metal layer is a copper layer.

In some implementations, a DBM substrate can be formed by bonding one or more of the metal layers (e.g., first metal layer, second metal layer) to the insulating layer. In some implementations, one or more of the metal layers can be bonded to the insulating layer using, for example, a high-temperature process.

Returning to FIG. 5, operation 504 is shown to involve coupling a semiconductor die with the internal substrate prepared at operation 502 (i.e., internal substrate 602). As has been mentioned, the apparatus may include a plurality of semiconductor dies each physically coupled with the internal substrate and integrated within the device package. As such, the semiconductor die coupled to the internal substrate at FIG. 5 may be included as one of a plurality of semiconductor dies (e.g., four semiconductor dies each implementing a field effect transistor in certain examples, as has been described) that are all coupled with the internal substrate as part of operation 504.

To illustrate, FIG. 6B shows a plurality of semiconductor dies 604 being physically coupled with internal substrate 602 in accordance with principles described herein. Based on the patterning of the conductive material (the metal layer) of internal substrate 602, as well as electrical connections that will be added at a later step, the four semiconductor dies 604 may be electrically interconnected such that, in this example, the apparatus being constructed will implement a half-bridge circuit configured for use in a power inverter module. In other examples, metal patterning, die fabrication and placement, and electrical connections made at later steps may serve to create various types of circuits with various functions as may serve a particular implementation.

In some implementations, one or more semiconductor dies (e.g., one or more semiconductor components) can be, or can include, a power semiconductor die. In some implementations, one or more semiconductor dies can be (or can be a portion of or can include) implemented by a metal-oxide-semiconductor field-effect transistor (MOSFET) device, an insulated-gate bipolar transistor (IGBT), an integrated circuit (IC), an inverter, a power conversion circuit, a bridge circuit, a fast recovery diode (FRDs), a diode, or the like. In some implementations, one or more semiconductor dies can be (or can be a portion of or can include) a component for an electrical vehicle (EV).

As illustrated in FIG. 6B, more than one semiconductor die can be included in certain implementations described herein. In some implementations, different semiconductor dies (when more than one semiconductor die is included in a given implementation) can be fabricated using different semiconductor substrates (e.g., a silicon carbide (SiC) substrate, a silicon (Si) substrate, a gallium nitride (GaN) substrate, etc.). In other words, different semiconductor dies may, for example, be fabricated on different semiconductor wafers or materials. This can be referred to as a hybrid die configuration. For example, a first semiconductor die can be formed using a SiC substrate and a second semiconductor die (separate from the first semiconductor die) can be formed using a silicon substrate. As another example, an IGBT can be fabricated using a SiC substrate, while a controller can be fabricated using a silicon substrate.

In example implementations, a package (e.g., a power module) can be a hybrid device package that includes a semiconductor die or a plurality of semiconductor dies that are integrated onto a unifying electronic power substrate (e.g., a ceramic substrate, a DBC substrate, an AMB substrate, an elastomeric substrate, an organic substrate, a phenolic substrate, or a PCB/FR-4 substrate). In some implementations, multiple semiconductor devices (e.g., can be fabricated on the same substrate such as a SiC substrate) suitable for high power applications.

The coupling of the one or more semiconductor dies at operation 504 may include physically and electrically coupling the semiconductor dies 604 with the internal substrate by a solder or sinter material. For example, operation 504 may include coupling, by a solder or sinter material, the plurality of semiconductor dies 604 with internal substrate 602 for integration within the device package (where the coupling of the particular semiconductor die referred to in operation 504 is performed as part of the coupling of the plurality of semiconductor dies).

As mentioned above, soldering can be, or can include, a process of joining two surfaces (e.g., metal surfaces) together using a molten filler metal (e.g., metal alloy, Tin (Sn), Lead (Pb), Silver (Ag), Copper (Cu), etc.) that can be referred to as a solder or solder material.

In some implementations, sintering can be or can include a process of fusing particles together into one solid mass by using, for example, a combination of pressure and/or heat without melting the materials. In some implementations, sintering can include making a material (e.g., a powdered material) coalesce into a solid or porous mass by heating it, and usually also compressing the material, without liquefaction. In some implementations, materials that can be used for sintering can include metals such as silver (Ag), copper (Cu) and/or metal alloys. In some implementations, sintered connections can have desirable electrical and/or thermal conductivity, durability, and a relatively high melting temperature.

In some implementations, one or more of the components described herein can be coupled using materials such as, for example, a solder, a sintering (e.g., silver sintering, copper sintering) material, and/or other metal-to-metal type bonding materials. In some implementations, a coupling of components can be performed using, for example, a solder process, a sintering process (e.g., a silver sintering process, copper sintering process), and/or other metal-to-metal type bonding processes.

It will be understood that, while semiconductor dies 604 may be soldered or sintered to internal substrate 602 during the fabrication of the apparatus (e.g., an implementation of apparatus 100), it may be desirable to avoid soldering or sintering the finished apparatus to an external substrate using these high-heat methods. Thus, as has been described and as will be detailed further with respect to later operations of method 500, solderless, low-heat techniques (e.g., acoustic based techniques such as ultrasonic welding described below) may be used at these later steps even if solder or sinter processes are used at operation 504.

While semiconductor dies 604 are shown in the example of FIG. 6B to be disposed on a surface of internal substrate 602, it will be understood that, in some implementations, one or more semiconductor dies can be embedded within a layer (rather than surface mounted). For example, one or more semiconductor dies can be disposed within a recess or cavity of a layer (e.g., a substrate, a printed circuit board, a conductive layer, an insulating layer, etc.).

Returning to FIG. 5, operation 506 is shown to involve fabricating a metal portion (e.g., a conductive portion, also referred to as a leadframe) of a device package with hybrid-material leads such as have been described. This fabrication operation may involve several steps of a process. Accordingly, FIG. 6C shows an example process with several steps 606-1, 606-2, and 606-3 for fabricating the metal portion of a device package to include hybrid-material leads in accordance with principles described herein. FIG. 6D further illustrates certain aspects of this fabrication process.

As shown in FIG. 6C, step 606-1 involves skiving (e.g., shaving, paring, cutting, scraping, etc.) off a strip of the second conductive material from a larger item of the second conductive material. To illustrate, FIG. 6D shows a strip 608-1 of a second conductive material (e.g., aluminum, as shown by the Key in FIG. 6D) being skived off of a larger item 608-2 of the second conductive material using a skiving tool 610 configured to remove a thin strip, as shown.

As further shown in FIG. 6C, step 606-2 involves cladding (e.g., covering, sheathing, encasing, lining, etc.) the skived item of the second conductive material with a strip of the first conductive material configured to replace the strip of second conductive material (and, in some cases, to also apply additional material than was removed). To illustrate, FIG. 6D shows a strip 612 of the first conductive material (e.g., copper, as shown by the Key in FIG. 6D) being cladded, using a cladding tool 614, onto the skived item of the second conductive material (i.e., item 608-2 after strip 608-1 has been skived off). As shown, the result 616 of the cladding at step 606-2 is a skived item of the second conductive material cladded with the strip of the first conductive material.

As further shown in FIG. 6C, step 606-3 then involves forming a plurality of leads from this cladded result 616 (i.e., from the skived item of the second conductive material cladded with the strip of the first conductive material). Leads formed from this result 616 of the skiving and cladding process may implement hybrid-material leads as have been described herein. More particularly, each lead formed from result 616 of this process may have both: 1) a first side on which the first conductive material is disposed, the first side being configured to physically contact an ultrasonic welding tool while an ultrasonic field is produced; and 2) a second side opposite the first side and on which the second conductive material is disposed, the second side being configured to physically contact the external substrate while the ultrasonic field is produced.

While the Key in FIG. 6D provides examples for what conductive materials may be used to form the hybrid-material leads (i.e., a first conductive material being copper and a second conductive material being aluminum), it will be understood that other substances may implement the conductive materials used to form hybrid-material leads in other implementations. The first conductive material may have a higher strength than the second conductive material so that the first material may rigidly maintain its structure when the second material plastically deforms under influence of an acoustic field (e.g., an ultrasonic sound field) applied at a particular frequency and intensity. For example, the first conductive material (forming a core) could be implemented by a substance such as copper, aluminum, titanium, stainless steel, tool steels (e.g., SK, SKS, SKD, SKH, etc.), or the like. Meanwhile, the second conductive material (forming a base) could be implemented by a substance such as aluminum, iron, stainless steel, or the like (where the selected substance for the second conductive material is lower strength than the material selected as the first conductive material so that it will plastically deform in an ultrasonic field before the first material deforms).

FIG. 6D also shows several types of overlays (“Overlay Types”) including a single lay 618-1, a side lay 618-2, a center lay 618-3, and a double side lay 618-4. While the skiving and cladding process illustrated in FIG. 6D shows an example of the center lay 618-3 and various example hybrid-material leads illustrated herein show examples of the single lay 618-1, it will be understood that any of these or other overlay types (e.g., double lays, up-down side lays, reverse lays, etc.) could be used as may serve a particular implementation. Additionally, while not explicitly shown, various types of inlays or edge lays could also be used to similar effect. For instance, possible inlay styles could include a full inlay in which the first material is sandwiched on top and bottom by the second material, a center inlay in which the first material is surrounded on all four sides by the second material, a side or double side inlay similar to side lay 618-2 or double side lay 618-4 but with an added layer of second conductive material on top of the first material, and so forth. Edge lays could be manufactured slightly differently by cladding a strip of the first material on the side edge (rather than the top and/or bottom) of the item of second material.

Returning to FIG. 5, operation 508 is shown to involve mounting the internal substrate on the metal portion of the device package fabricated at operation 506 (also referred to as a leadframe or a conductive portion in cases when non-metal conductive materials are used). Using the techniques described above, the metal portion of the device package may be made to include a plurality of leads each constructed of the first conductive material and the second conductive material. As has been described, the first conductive material may be configured to maintain a rigid structure within an acoustic field (e.g., an ultrasonic field produced by an ultrasonic welding tool) while the second conductive material may be configured to plastically deform within the acoustic field (e.g., so as to bond to an external substrate when an ultrasonic or other low-heat, acoustic-based welding tool is used).

To illustrate, FIG. 6E shows a perspective view of the internal substrate being mounted on the metal portion of the device package in accordance with principles described herein. More particularly, FIG. 6E shows the internal substrate 602 with the coupled semiconductor dies 604 (as described above and illustrated in FIG. 6B) being mounted to a leadframe 620 that has been fabricated with hybrid-material leads using principles described above (e.g., the process of FIG. 6C, etc.). Although referred to, by way of example, as a leadframe in this detailed description, it will be understood that leadframe 620 can include any type of conductive portion of a package (e.g., conductive portion, conductive terminal) that can provide an external connection point from a package. Accordingly, leadframe 620 can also be referred to as a conductive portion or metal portion of the device package. As shown by the mounting in FIG. 6E, one or more portions of the leadframe can be coupled to a pad (e.g., a bond pad) on at least a portion of a DBM substrate (e.g., internal substrate 602).

Returning to FIG. 5, operation 510 is shown to involve establishing electrical connections from the plurality of leads of the metal portion (e.g., leadframe 620) to the internal substrate (e.g., internal substrate 602) and the semiconductor die (e.g., semiconductor dies 604). To illustrate, FIG. 6F shows, within a straight-on view of the internal substrate mounted on the leadframe, electrical connections 622 that may be established between the plurality of hybrid-material leads of the device package (i.e., of leadframe 620) and the plurality of dies (i.e., semiconductor dies 604) on internal substrate 602. The connections shown in FIG. 6F are provided only for illustration purposes and it will be understood that any suitable connections may be made to achieve whatever objective there may be for the circuitry of the electronic component being produced. For instance, electrical connections 622 may be provided that connect the transistors implemented by semiconductor dies 604 in a manner that creates a half-bridge circuit with a particular pinout in one example.

The establishing of the electrical connections at operation 510 may be performed using any techniques or technologies as may serve a particular implementation. As one example, electrical connections 622 could be established using a soldering technique to bond conductive wires or clips to the plurality of leads, the internal substrate, and/or the semiconductor die. As another example, electrical connections 622 could be established using a sintering technique to bond the conductive wires or clips to the plurality of leads, the internal substrate, and/or the semiconductor die.

In example implementations, a first semiconductor die may be connected to a second semiconductor die, for example, by an electrical connection (e.g., a wirebond, an electrical clip) extending directly from the first die to the second die, or connected through a trace formed in the first conductive layer (e.g., a metal layer) of the electronic power substrate. Any of the plurality of semiconductor dies may be also connected to leadframe posts by electrical connections such as wirebonds or clips.

While conductive wires (also referred to as wirebonds) are shown in FIG. 6F, it will be understood that one or more wirebonds can be replaced with other types of conductive components. For example, in some implementations, one or more wirebonds can be replaced with one or more conductive clips. A conductive clip can be coupled to another component (e.g., an attach pad, a leadframe, a semiconductor die, etc.) using, for example, a solder (e.g., a soldering process), a sintered coupling (e.g., a sintering process), a weld, or other suitable couplings. In some implementations, one or more wirebonds and/or clips can function as an input and/or output power terminal, a signal terminal, a power terminal, or the like.

Returning to FIG. 5, operation 512 is shown to involve encasing the internal substrate, the semiconductor die, the electrical connections, and a portion of each of the plurality of leads in a molding material of the device package. To illustrate, FIG. 6G shows illustrative molding material 624 in which other components of the device package are encased in accordance with principles described herein. In some implementations, the mold material (e.g., molding material or compound) can be or can include a non-conducting layer/material. For example, molding material 624 may be or include an organic material (e.g., a polymer or plastic material such as epoxy, silicone, phenolic resin, etc.), an inorganic material (e.g., a non-conductive ceramic or conductive metal material, etc.) or other suitable materials as may serve a particular implementation.

Returning to FIG. 5, operation 514 is shown to involve finishing the apparatus, or, in other words, performing any of various final steps to prepare the fully-packaged electronic component for sale or use as part of a particular application (e.g., for use in the construction of a device such as a power inverter module such as power inverter module 400 described above). This finishing the apparatus may involve several steps of a process. Accordingly, FIG. 6H shows an example process with several steps 626-1, 626-2, and 626-3 for finishing the electronic component. It will be understood that, like other methods and processes described herein, the steps of this process are not necessarily exclusive (i.e., there may be additional finishing steps performed in certain implementations), not necessarily required (i.e., there may be fewer finishing steps performed in certain implementations), and not necessarily performed in the order suggested by process illustration.

As shown in FIG. 6H, step 626-1 involves trimming the plurality of leads from other parts of the metal portion of the device package. For example, any excess material of leadframe 620 surrounding the molded chip may be removed using a precision cutting tool to ensure that the hybrid-material leads are the correct length and shape for the desired package. Additionally, any excess molding compound that may have flowed onto the leads or other unwanted areas may be trimmed away at this step to ensure proper electrical and mechanical performance.

Step 626-2 involves forming the plurality of leads into a desired shape for the final package. For example, while the leads may be flat and linear up to this point (not shown in leadframe 620 above), the leads could be bent into a desired non-linear shape (e.g., a J-lead or gull-wing shape, etc.) at this step to facilitate automated assembly and coupling onto the external substrate (e.g., a printed circuit board (PCB)). In certain examples, the overall shape of the package may also be refined at this stage, such as by rounding edges of the molding, creating specific notches, or the like. Markings may also be made on the device package as part of the finishing process, either as part of one of steps 626-1 to 626-3 or as an additional step not explicitly shown.

Step 626-3 involves testing the finished apparatus constructed by performance of method 500. For example, an automated testing machine may run a gamut of tests to ensure proper functionality of the finished apparatus. Additionally, an assessment may be made as part of the testing as to whether the mechanical aspects of the apparatus (e.g., the leads, the molding, etc.) all meet desired specifications.

Returning to FIG. 5, operation 516 is shown to involve solderlessly coupling the finished apparatus from operation 514 to an external substrate. For example, as has been mentioned, the solderless coupling (which may also avoid sintering and other high-heat coupling techniques) may be achieved using an acoustic-based tool (e.g., an ultrasonic welding tool) to bond the finished apparatus to the external substrate. For example, the external substrate may be implemented by a PCB of a device within which the electronic component (i.e., the finished apparatus) is to be integrated or with which the electronic component is to be otherwise utilized. Referring to certain examples described above, for example, the finished apparatus could implement a half-bridge circuit (e.g., any of half-bridge circuits 402-1 to 402-3) and the device for which the apparatus is intended could be a power inverter module (e.g., power inverter module 400).

To illustrate this final operation in which the apparatus is used in its intended application, FIG. 6I shows example aspects of solderless coupling of the apparatus with an external substrate in accordance with principles described herein. More particularly, the finished apparatus fabricated by way of method 500 (i.e., by performing operations 502 to 514 described above) is shown in FIG. 6I to include the molding material 624 described above, along with a plurality of hybrid-material leads 628 emerging therefrom. The apparatus (and, more particularly, each hybrid-material lead 628 of the apparatus) is to be coupled to an external substrate 630, such as a rigid or flexible PCB (e.g., a PCB of a power inverter module in one example) or another suitable substrate configured to host the electronic component. While not explicitly shown in FIG. 6I, it will be understood that various pads, traces, and other components of external substrate 630 may have been prepared specifically for this apparatus and its particular pinout. As such, part of the coupling of the apparatus with external substrate 630 at operation 516 may include properly aligning the apparatus with the PCB so that each of hybrid-material leads 628 will be coupled to the desired pad that is configured to receive it.

To achieve the solderless coupling, the example of FIG. 6I shows an ultrasonic welding tool 632 that is configured to produce an ultrasonic field 634 (e.g., an acoustic field at ultrasonic frequencies such as between 20 kHz and 40 kHz in certain examples). While not shown in detail, it will be understood that ultrasonic welding tool 632 may include various aspects such as a power supply, a converter, a booster, a horn, a sonotrode, and so forth to facilitate the production and targeting of the ultrasonic field 634 onto a localized weld zone in which the hybrid-material lead 628 is disposed. When the hybrid-material lead 628 is properly aligned with the substrate, the ultrasonic welding tool 632 is properly positioned over the lead, an appropriate amount of pressure is applied, and ultrasonic field 634 is produced, the lead and the substrate may be joined or coupled together. More particularly, the second conductive material of the hybrid-material lead 628 may plastically deform (even as the first conductive material maintains a rigid structure to keep the lead from losing its shape) to form a strong bond with the external substrate 630 (e.g., with a pad on the PCB that has been prepared for this purpose).

While some heat is locally produced by the energy of the acoustic field, the heat is considerably less, or at least considerably more localized to the hybrid-material lead, than a comparable solder-based or sinter-based coupling, which, as described above, would be likely to produce heat within the device package that could cause problems. The acoustic (i.e., ultrasonic) vibrations of ultrasonic field 634 may be applied to the surfaces being joined (i.e., the zone where the lead meets the substrate) and may cause friction between the surfaces to locally heat the interface sufficiently for the second conductive material on the lead to soften and plastically deform. At this point, the surfaces may interlock at a microscopic level to form a strong metallurgical bond, even though no solder or sintering material has been introduced and no reflowing of metal has occurred. The resulting bond may be generated quickly and efficiently to produce a joint as strong (or nearly as strong) as the parent metals.

The following examples describe implementations (e.g., apparatuses, methods, devices, etc.) of hybrid-material leads for solderless coupling of an electronic component in accordance with principles described herein.

Example 1: An apparatus comprising: a first substrate; a semiconductor die physically coupled with the first substrate; and a plurality of leads extending from a device package containing the first substrate and the semiconductor die, the plurality of leads including a lead that is electrically coupled with the semiconductor die and constructed of a first conductive material and a second conductive material, wherein: the first conductive material is configured to maintain a rigid structure within an acoustic field, and the second conductive material is configured to plastically deform within the acoustic field to bond to a second substrate.

Example 2: The apparatus of any of the preceding examples, wherein the first substrate is an internal substrate contained within the device package and the second substrate is an external substrate to which the device package is coupled.

Example 3: The apparatus of any of the preceding examples, wherein: the acoustic field is an ultrasonic field produced by an ultrasonic welding tool; the first conductive material is disposed on a first side of the lead configured to physically contact the ultrasonic welding tool while the ultrasonic field is produced; and the second conductive material is disposed on a second side of the lead opposite the first side and configured to physically contact the external substrate while the ultrasonic field is produced.

Example 4: The apparatus of any of the preceding examples, comprising a plurality of semiconductor dies each physically coupled with the internal substrate and integrated within the device package, the semiconductor die being included as one of the plurality of semiconductor dies.

Example 5: The apparatus of any of the preceding examples, wherein: the plurality of semiconductor dies includes four semiconductor dies each implementing a field effect transistor; and the four semiconductor dies are electrically interconnected such that the apparatus implements a half-bridge circuit configured for use in a power inverter module.

Example 6: The apparatus of any of the preceding examples, wherein the semiconductor die is physically and electrically coupled with the internal substrate by a solder or sinter material.

Example 7: The apparatus of any of the preceding examples, wherein each lead of the plurality of leads is configured to bond to the external substrate, the external substrate being implemented by a printed circuit board of a power inverter module.

Example 8: The apparatus of any of the preceding examples, wherein the internal substrate is a direct-bonded metal (DBM) substrate implemented by a patterned layer of metal bonded to a ceramic substrate.

Example 9: The apparatus of any of the preceding examples, wherein the first conductive material is copper and the second conductive material is aluminum.

Example 10: The apparatus of any of the preceding examples, wherein the semiconductor die is a silicon carbide (SiC) die implementing a field effect transistor.

Example 11: A method comprising: preparing an internal substrate; coupling a semiconductor die with the internal substrate; mounting the internal substrate on a metal portion of a device package, the metal portion including a plurality of leads each constructed of a first conductive material and a second conductive material, the first conductive material being configured to maintain a rigid structure within an ultrasonic field produced by an ultrasonic welding tool and the second conductive material being configured to plastically deform within the ultrasonic field to bond to an external substrate; establishing electrical connections from the plurality of leads to the internal substrate and the semiconductor die; and encasing the internal substrate, the semiconductor die, the electrical connections, and a portion of each of the plurality of leads in a molding material of the device package.

Example 12: The method of any of the preceding examples, further comprising fabricating the metal portion of the device package with the plurality of leads, the fabricating including: skiving off a strip of the second conductive material from a larger item of the second conductive material; cladding the skived item of the second conductive material with a strip of the first conductive material configured to replace the strip of the second conductive material; and forming the plurality of leads from the skived item of the second conductive material cladded with the strip of the first conductive material such that the plurality of leads includes a lead having: a first side on which the first conductive material is disposed and configured to physically contact the ultrasonic welding tool while the ultrasonic field is produced; and a second side opposite the first side and on which the second conductive material is disposed and configured to physically contact the external substrate while the ultrasonic field is produced.

Example 13: The method of any of the preceding examples, wherein the first conductive material is copper and the second conductive material is aluminum.

Example 14: The method of any of the preceding examples, comprising coupling, by a solder or sinter material, a plurality of semiconductor dies with the internal substrate for integration within the device package, the coupling of the semiconductor die being performed as part of the coupling of the plurality of semiconductor dies.

Example 15: The method of any of the preceding examples, wherein the establishing of the electrical connections includes using a soldering technique to bond conductive wires or clips to the plurality of leads, the internal substrate, and the semiconductor die.

Example 16: The method of any of the preceding examples, wherein the establishing of the electrical connections includes using a sintering technique to bond conductive wires or clips to the plurality of leads, the internal substrate, and the semiconductor die.

Example 17: The method of any of the preceding examples, further comprising: trimming the plurality of leads from other parts of the metal portion of the device package; forming the plurality of leads into a non-linear shape; and testing a finished apparatus constructed by performing the method.

Example 18: The method of any of the preceding examples, further comprising using the ultrasonic welding tool to bond, to the external substrate, a finished apparatus constructed by performing the method; wherein the external substrate is implemented by a printed circuit board of a power inverter module.

Example 19: A power inverter module comprising: a substrate; a heatsink; and a plurality of chips each physically coupled with the heatsink and electrically coupled with the substrate, the plurality of chips including a chip having a plurality of semiconductor dies contained within a device package from which a plurality of leads extends, the plurality of leads including a lead constructed of a first conductive material and a second conductive material, wherein: the first conductive material is configured to maintain a rigid structure within an acoustic field, and the second conductive material is configured to plastically deform within the acoustic field to bond to the substrate while the acoustic field is produced and the lead is in physical contact with the substrate.

Example 20: The power inverter module of any of the preceding examples, wherein the plurality of chips includes three chips each including four respective semiconductor dies implementing field effect transistors that are electrically interconnected to implement respective half-bridge circuits.

Example 21: The power inverter module of any of the preceding examples, wherein: the acoustic field is an ultrasonic field produced by an ultrasonic welding tool; and each of the plurality of chips is bonded to the substrate by an ultrasonic welding technique involving less heat than a soldering technique.

A number of embodiments have been described. Nevertheless, it will be understood that various modifications may be made without departing from the spirit and scope of the specification.

It will also be understood that when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application may be amended to recite illustrative relationships described in the specification or shown in the figures.

The various apparatus and techniques described herein may be implemented using various semiconductor processing and/or packaging techniques. Some embodiments may be implemented using various types of semiconductor processing technologies associated with semiconductor substrates including, but not limited to, for example, Silicon (Si), Gallium Arsenide (GaAs), Silicon Carbide (SiC), and/or so forth.

It will also be understood that when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present.

Although the terms directly on, directly connected to, or directly coupled to may not be used throughout the detailed description, elements that are shown as being directly on, directly connected or directly coupled can be referred to as such. The claims of the application may be amended to recite illustrative relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

In addition, the logic flows depicted in the figures do not require the particular order shown, or sequential order, to achieve desirable results. In addition, other steps may be provided, or steps may be eliminated, from the described flows, and other components may be added to, or removed from, the described systems. Accordingly, other embodiments are within the scope of the following claims.

It will be understood that, although the terms first, second, etc. may be used herein to describe various elements, these elements should not be limited by these terms. These terms are only used to distinguish one element from another. A first element could be termed a second element, and, similarly, a second element could be termed a first element, without departing from the scope of the implementations of the disclosure. As used herein, the term and/or includes any and all combinations of one or more of the associated listed items.

While certain features of the described implementations have been illustrated as described herein, many modifications, substitutions, changes, and equivalents may occur to those skilled in the art. It is therefore to be understood that the appended claims are intended to cover such modifications and changes as fall within the scope of the implementations. It will be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components, and/or features of the different implementations described. As such, the scope of the present disclosure is not limited to the particular combinations hereafter claimed, but instead extends to encompass any combination of features or example implementations described herein irrespective of whether or not that particular combination has been specifically enumerated in the accompanying claims at this time.

What is claimed is:

1. An apparatus comprising:
a first substrate;
a semiconductor die physically coupled with the first substrate; and
a plurality of leads extending from a device package containing the first substrate and the semiconductor die, the plurality of leads including a lead that is electrically coupled with the semiconductor die and constructed of a first conductive material and a second conductive material, wherein:
the first conductive material is configured to maintain a rigid structure within an acoustic field, and
the second conductive material is configured to plastically deform within the acoustic field to bond to a second substrate.

2. The apparatus of claim 1, wherein the first substrate is an internal substrate contained within the device package and the second substrate is an external substrate to which the device package is coupled.

3. The apparatus of claim 2, wherein:
the acoustic field is an ultrasonic field produced by an ultrasonic welding tool;
the first conductive material is disposed on a first side of the lead configured to physically contact the ultrasonic welding tool while the ultrasonic field is produced; and
the second conductive material is disposed on a second side of the lead opposite the first side and configured to physically contact the external substrate while the ultrasonic field is produced.

4. The apparatus of claim 2, comprising a plurality of semiconductor dies each physically coupled with the internal substrate and integrated within the device package, the semiconductor die being included as one of the plurality of semiconductor dies.

5. The apparatus of claim 4, wherein:
the plurality of semiconductor dies includes four semiconductor dies each implementing a field effect transistor; and
the four semiconductor dies are electrically interconnected such that the apparatus implements a half-bridge circuit configured for use in a power inverter module.

6. The apparatus of claim 2, wherein the semiconductor die is physically and electrically coupled with the internal substrate by a solder or sinter material.

7. The apparatus of claim 2, wherein each lead of the plurality of leads is configured to bond to the external substrate, the external substrate being implemented by a printed circuit board of a power inverter module.

8. The apparatus of claim 2, wherein the internal substrate is a direct-bonded metal (DBM) substrate implemented by a patterned layer of metal bonded to a ceramic substrate.

9. The apparatus of claim 1, wherein the first conductive material is copper and the second conductive material is aluminum.

10. The apparatus of claim 1, wherein the semiconductor die is a silicon carbide (SiC) die implementing a field effect transistor.

11. A method comprising:
preparing an internal substrate;
coupling a semiconductor die with the internal substrate;
mounting the internal substrate on a metal portion of a device package, the metal portion including a plurality of leads each constructed of a first conductive material and a second conductive material, the first conductive material being configured to maintain a rigid structure within an ultrasonic field produced by an ultrasonic welding tool and the second conductive material being configured to plastically deform within the ultrasonic field to bond to an external substrate;
establishing electrical connections from the plurality of leads to the internal substrate and the semiconductor die; and
encasing the internal substrate, the semiconductor die, the electrical connections, and a portion of each of the plurality of leads in a molding material of the device package.

12. The method of claim 11, further comprising fabricating the metal portion of the device package with the plurality of leads, the fabricating including:
skiving off a strip of the second conductive material from a larger item of the second conductive material;
cladding the skived item of the second conductive material with a strip of the first conductive material configured to replace the strip of the second conductive material; and
forming the plurality of leads from the skived item of the second conductive material cladded with the strip of the first conductive material such that the plurality of leads includes a lead having:
a first side on which the first conductive material is disposed and configured to physically contact the ultrasonic welding tool while the ultrasonic field is produced; and
a second side opposite the first side and on which the second conductive material is disposed and configured to physically contact the external substrate while the ultrasonic field is produced.

13. The method of claim 11, wherein the first conductive material is copper and the second conductive material is aluminum.

14. The method of claim 11, comprising coupling, by a solder or sinter material, a plurality of semiconductor dies with the internal substrate for integration within the device package, the coupling of the semiconductor die being performed as part of the coupling of the plurality of semiconductor dies.

15. The method of claim 11, wherein the establishing of the electrical connections includes using a soldering technique to bond conductive wires or clips to the plurality of leads, the internal substrate, and the semiconductor die.

16. The method of claim 11, wherein the establishing of the electrical connections includes using a sintering technique to bond conductive wires or clips to the plurality of leads, the internal substrate, and the semiconductor die.

17. The method of claim 11, further comprising:
trimming the plurality of leads from other parts of the metal portion of the device package;
forming the plurality of leads into a non-linear shape; and
testing a finished apparatus constructed by performing the method.

18. The method of claim 11, further comprising using the ultrasonic welding tool to bond, to the external substrate, a finished apparatus constructed by performing the method;
wherein the external substrate is implemented by a printed circuit board of a power inverter module.

19. A power inverter module comprising:
a substrate;
a heatsink; and
a plurality of chips each physically coupled with the heatsink and electrically coupled with the substrate, the plurality of chips including a chip having a plurality of semiconductor dies contained within a device package from which a plurality of leads extends, the plurality of leads including a lead constructed of a first conductive material and a second conductive material, wherein:
the first conductive material is configured to maintain a rigid structure within an acoustic field, and
the second conductive material is configured to plastically deform within the acoustic field to bond to the substrate while the acoustic field is produced and the lead is in physical contact with the substrate.

20. The power inverter module of claim 19, wherein the plurality of chips includes three chips each including four respective semiconductor dies implementing field effect transistors that are electrically interconnected to implement respective half-bridge circuits.

21. The power inverter module of claim 19, wherein:
the acoustic field is an ultrasonic field produced by an ultrasonic welding tool; and
each of the plurality of chips is bonded to the substrate by an ultrasonic welding technique involving less heat than a soldering technique.
